(19) United States
(12) Patent Application Publication
(10) Pub. No.: US 2025/0174527 A1
(43) Pub. Date: May 29, 2025

(54) SEMICONDUCTOR DEVICE

(71) Applicant: ROHM CO., LTD., Kyoto-shi (JP)

(72) Inventor: Ryuta YAGINUMA, Kyoto-shi (JP)

(21) Appl. No.: 19/040,553

(22) Filed: Jan. 29, 2025

Related U.S. Application Data
(63) Continuation of application No. PCT/JP2023/027007, filed on Jul. 24, 2023.

(30) Foreign Application Priority Data
Aug. 5, 2022 (JP) 2022-125359

(51) Int. Cl. H01L 23/495; H01L 23/00; H01L 23/31; H01L 23/373; H10D 80/20

(52) U.S. Cl. CPC H01L 23/49562; H01L 23/49582; H01L 24/32; H01L 23/3121; H01L 23/3736; H01L 24/45; H01L 24/48; H01L 24/73; H01L 2224/32; H01L 2224/45124; H01L 2224/45144; H01L 2224/45147; H01L 2224/48245; H01L 2224/48465; H01L 2224/73215; H01L 2224/73265; H01L 2924/13091; H10D 80/251

(57) ABSTRACT

A semiconductor device includes: a semiconductor element including a semiconductor layer and a first electrode disposed on one side in a thickness direction with respect to the semiconductor layer; a first conductive member bonded to the first electrode; a second conductive member bonded to the semiconductor element on the other side in the thickness direction; and a sealing resin including a first resin surface and a second resin surface respectively oriented toward the one side and the other side in the thickness direction and covering the semiconductor element and at least a portion of each of the first conductive member and the second conductive member. The first electrode includes a first metal layer that contains a metal having a higher thermal conductivity than solder.

### TECHNICAL FIELD

The present disclosure relates to semiconductor devices.

### BACKGROUND ART

JP-A-2021-158180 discloses an example of a conventional semiconductor device. The semiconductor device disclosed in the document includes an electrical conductor, a semiconductor element, a conductive member, and a sealing resin. The semiconductor element is mounted on the electrical conductor. The semiconductor element includes an electrode to which the conductive member is bonded using solder. The sealing resin covers at least a portion of each of the electrical conductor, the semiconductor element, and the conductive member.

### BRIEF DESCRIPTION OF THE DRAWINGS

FIG. 1 is a perspective view of a semiconductor device according to a first embodiment of the present disclosure.

FIG. 2 is a fragmentary perspective view of the semiconductor device according to the first embodiment of the present disclosure.

FIG. 3 is a plan view of the semiconductor device according to the first embodiment of the present disclosure.

FIG. 4 is a fragmentary plan view of the semiconductor device according to the first embodiment of the present disclosure.

FIG. 5 is a bottom view of the semiconductor device according to the first embodiment of the present disclosure.

FIG. 6 is a fragmentary bottom view of the semiconductor device according to the first embodiment of the present disclosure.

FIG. 7 is a side view of the semiconductor device according to the first embodiment of the present disclosure.

FIG. 8 is a sectional view taken along line VIII-VIII in FIG. 4.

FIG. 9 is a sectional view taken along line IX-IX in FIG. 4.

FIG. 10 is a fragmentary sectional view schematically showing a bonded structure according to the first embodiment, included in the semiconductor device of the present disclosure.

FIG. 11 is a fragmentary sectional view schematically showing an example of the bonded structure included in the semiconductor device according to the first embodiment of the present disclosure.

FIG. 12 is a fragmentary sectional view schematically showing another example of the bonded structure included in the semiconductor device according to the first embodiment of the present disclosure.

FIG. 13 is a fragmentary sectional view schematically showing a yet another example of the bonded structure included in the semiconductor device according to the first embodiment of the present disclosure.

FIG. 14 is a fragmentary sectional view schematically showing a yet another example of the bonded structure included in the semiconductor device according to the present disclosure.

FIG. 15 is a sectional view of a semiconductor device according to a first variation of the first embodiment of the present disclosure.

FIG. 16 is a perspective view of a semiconductor device according to a second embodiment of the present disclosure.

FIG. 17 is a fragmentary perspective view of the semiconductor device according to the second embodiment of the present disclosure.

FIG. 18 is a plan view of the semiconductor device according to the second embodiment of the present disclosure.

FIG. 19 is a fragmentary plan view of the semiconductor device according to the second embodiment of the present disclosure.

FIG. 20 is a bottom view of the semiconductor device according to the second embodiment of the present disclosure.

FIG. 21 is a fragmentary bottom view of the semiconductor device according to the second embodiment of the present

### DISCLOSURE

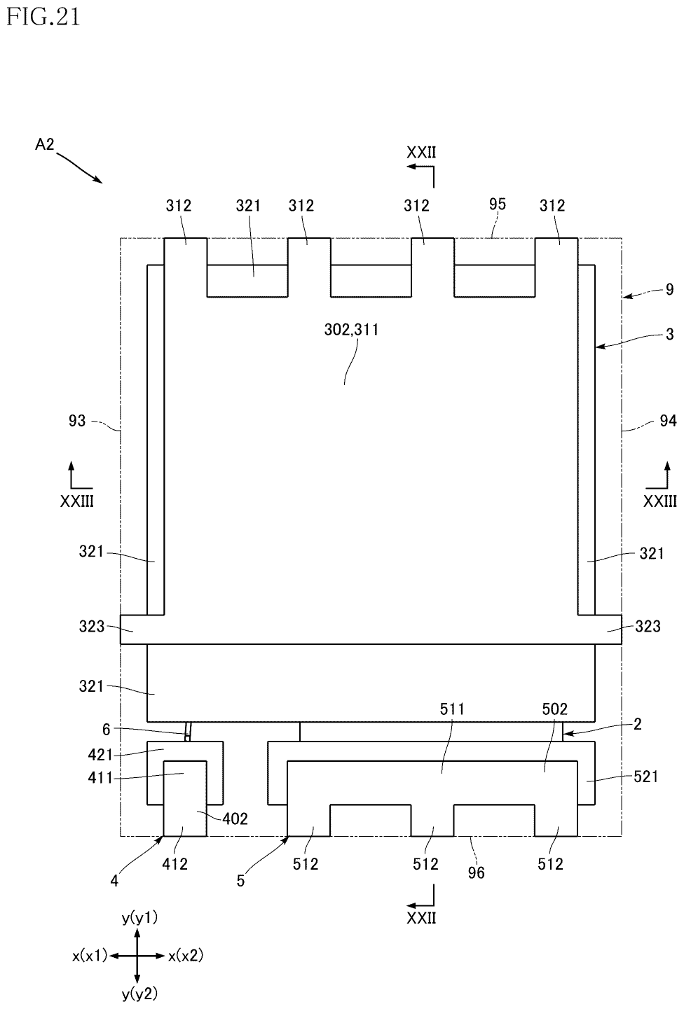

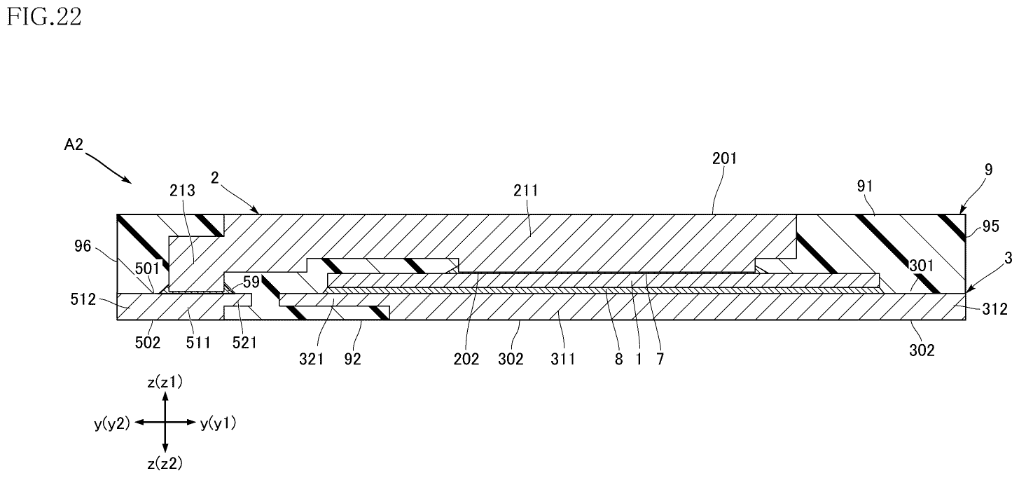

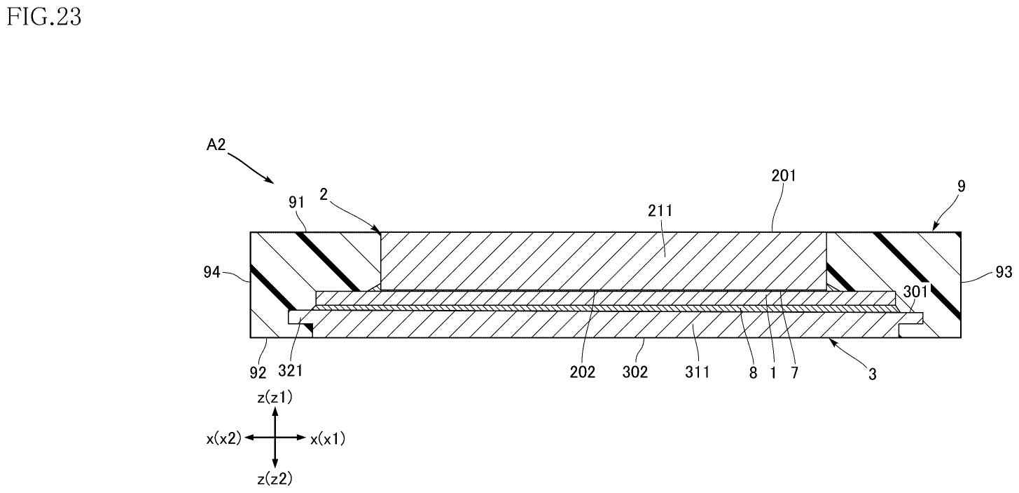

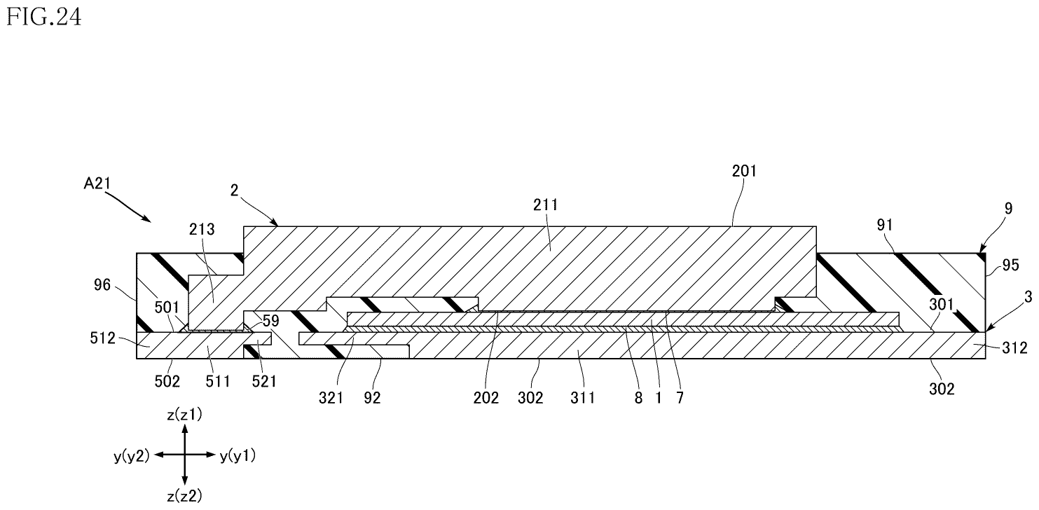

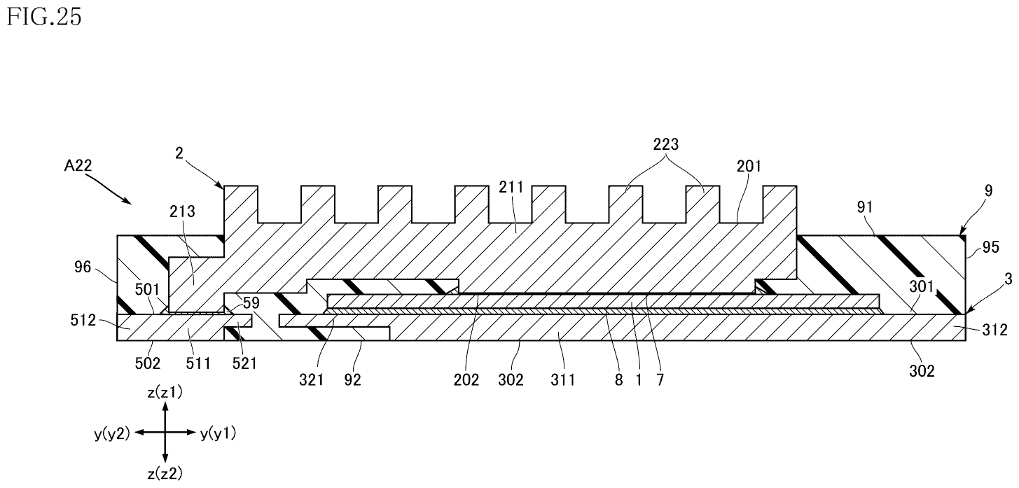

FIG. 22 is a sectional view taken along line XXII-XXII in FIG. 21.

FIG. 23 is a sectional view taken along line XXIII-XXIII in FIG. 21.

FIG. 24 is a sectional view of a semiconductor device according to a first variation of the second embodiment of the present disclosure.

FIG. 25 is a sectional view of a semiconductor device according to a second variation of the second embodiment of the present disclosure.

### DETAILED DESCRIPTION OF EMBODIMENTS

The following specifically describes preferred embodiments of the present disclosure with reference to the drawings.

In the present disclosure, the terms such as “first”, “second”, “third”, and so on are used merely as labels to identify the objects referred to by the terms and are not intended to impose a specific order or sequence on these objects.

In the description of the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Still further, “A surface A faces in a direction B (or is oriented toward a first side or an opposite second side in the direction B) is not limited, unless otherwise specifically noted, to the situation where the surface A forms an angle of 90° with the direction B but includes the situation where the surface A is inclined relative to the direction B.

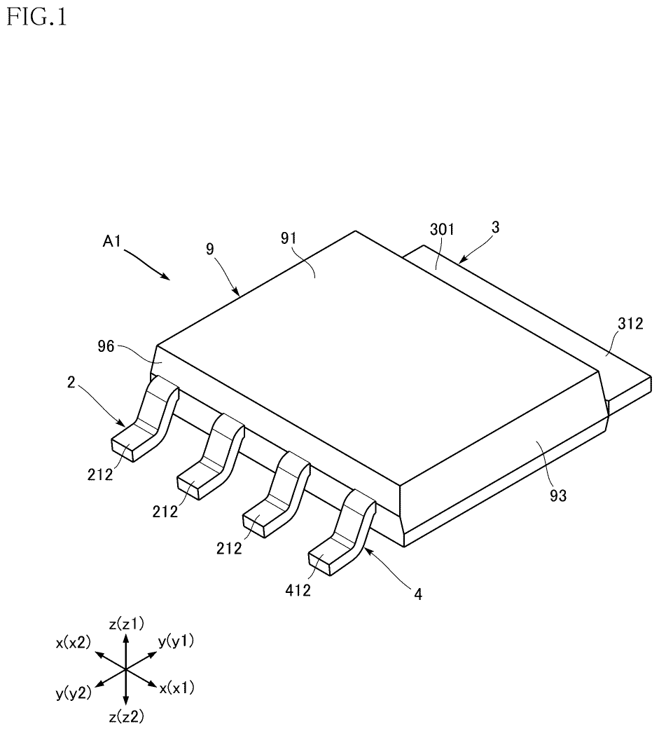

FIGS. 1 to 10 show a semiconductor device according to a first embodiment of the present disclosure. The semiconductor device A1 of this embodiment includes a semiconductor element 1, a first conductive member 2, a second conductive member 3, a third conductive member 4, a first bonding layer 7, a second bonding layer 8, and a sealing resin 9. The semiconductor device A1 is not limited to specific applications and may be used in electronic devices provided with power conversion circuits, such as DC-DC converters.

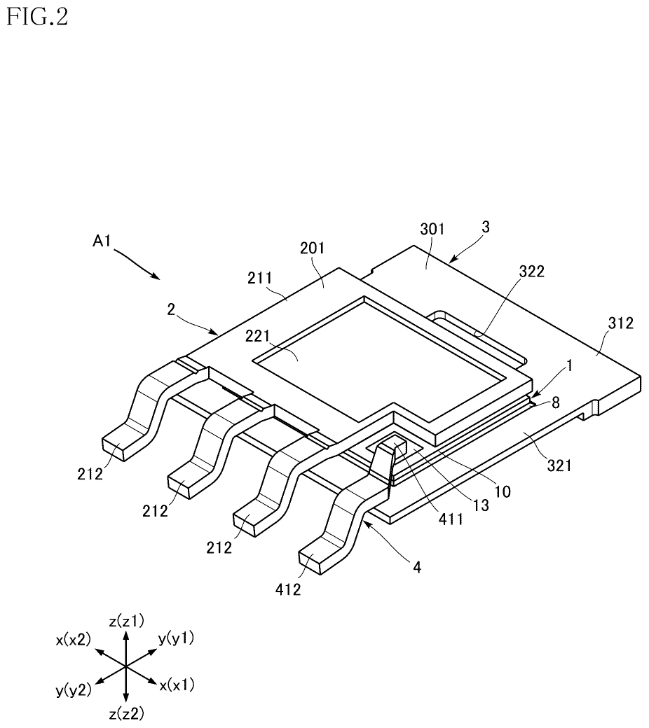

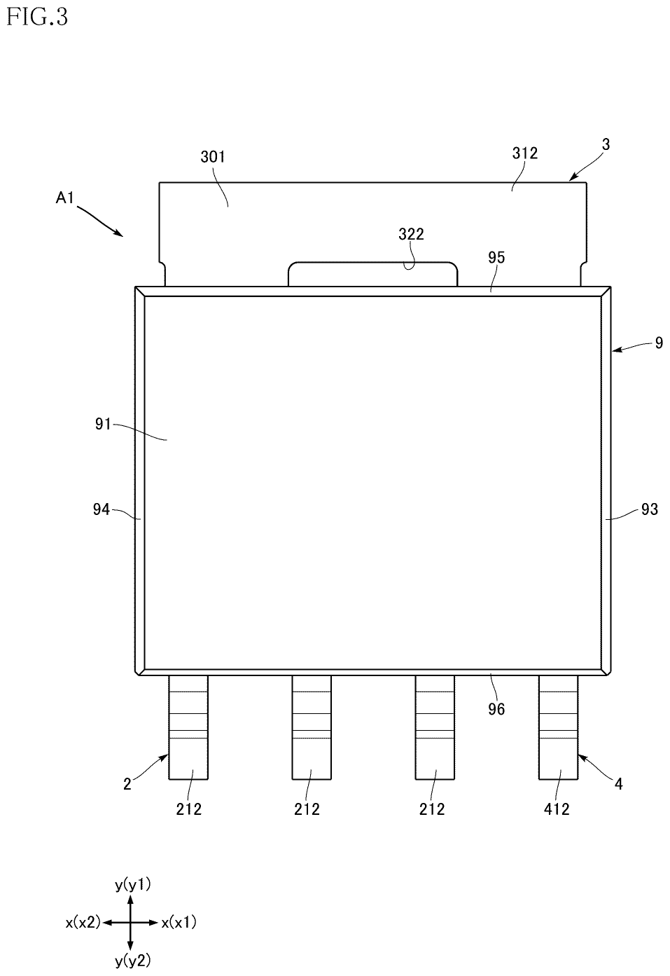

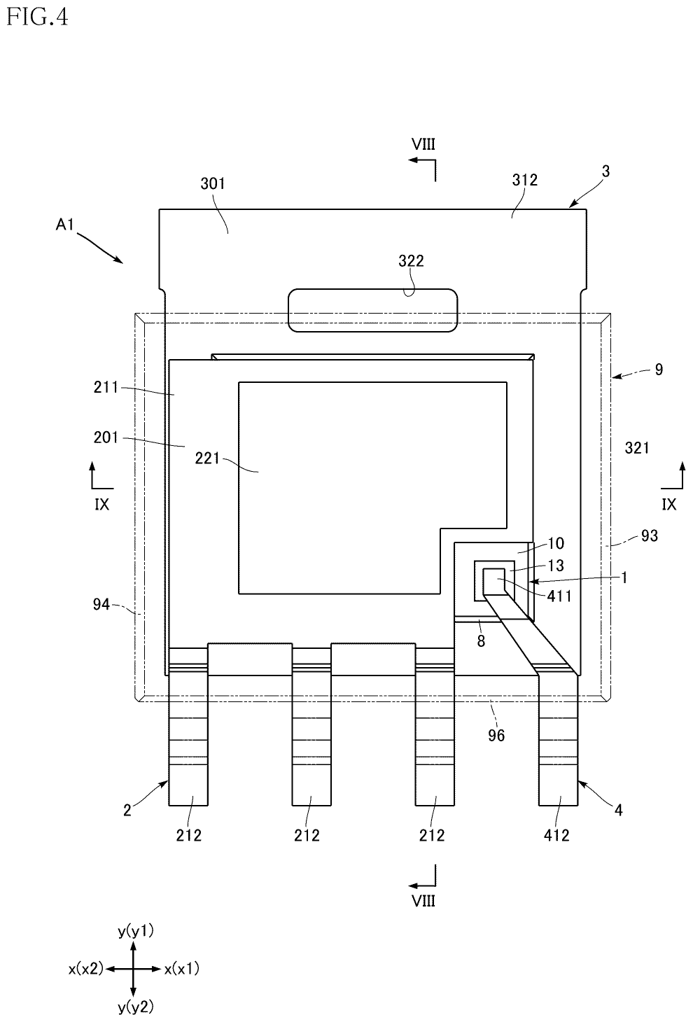

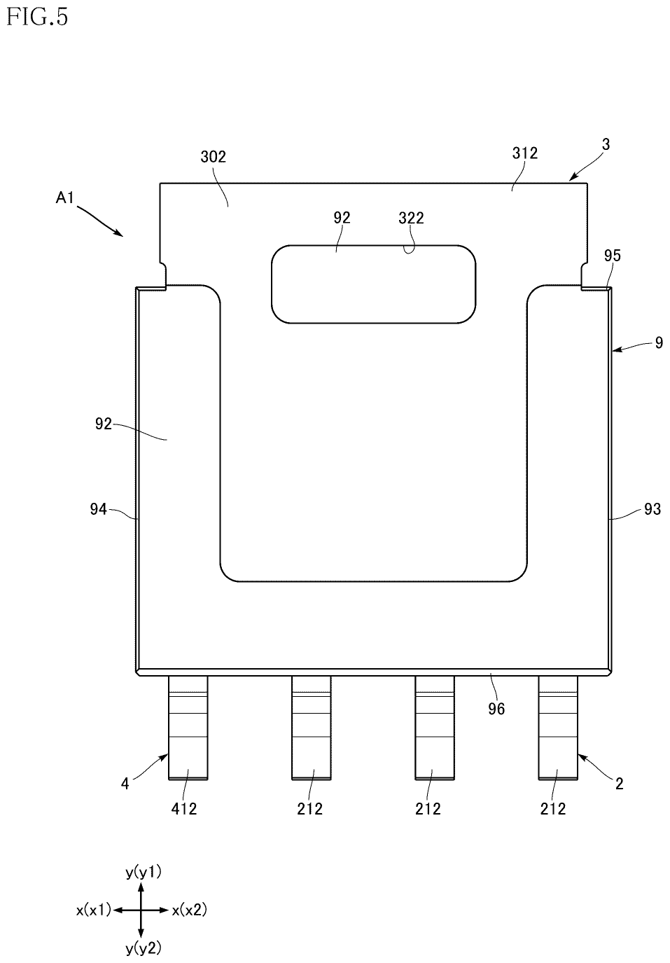

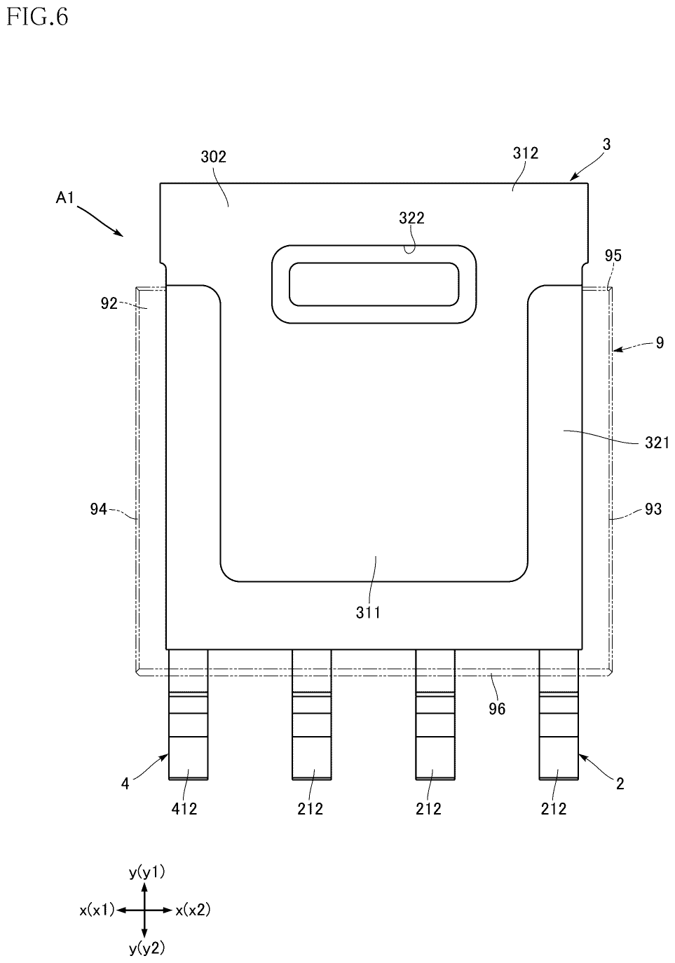

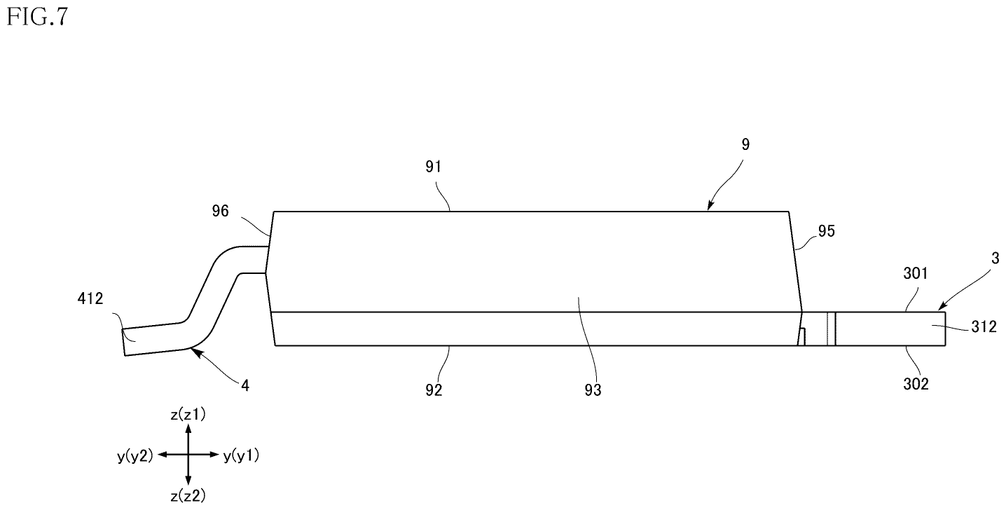

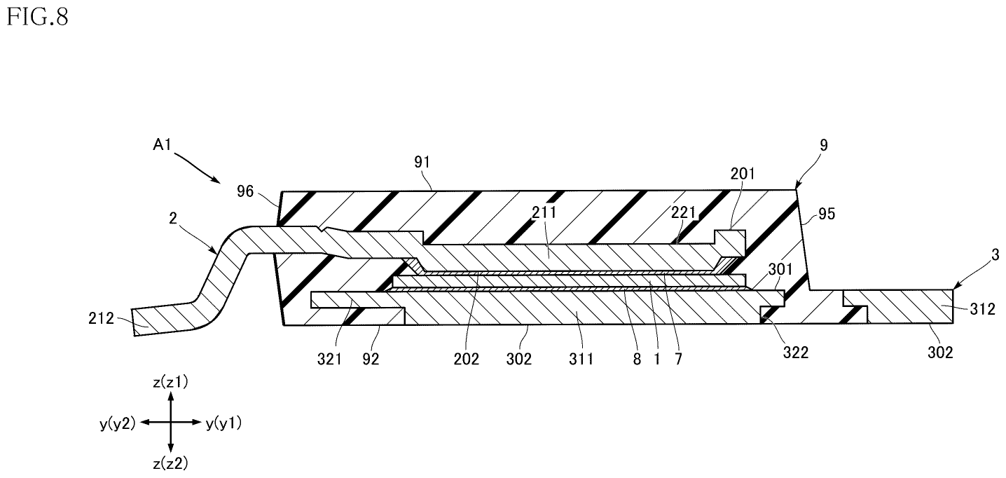

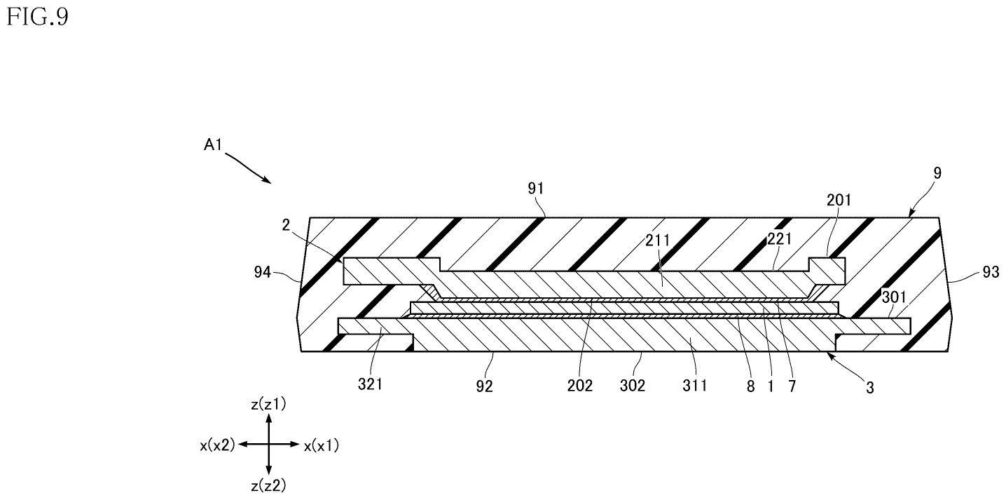

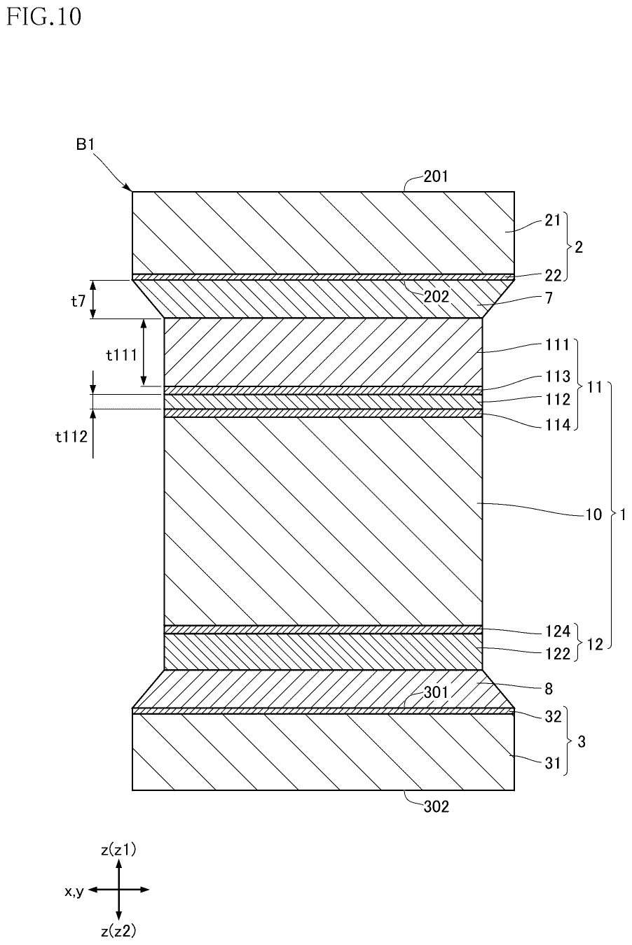

FIG. 1 is a perspective view of the semiconductor device A1. FIG. 2 is a fragmentary perspective view of the semiconductor device A1. FIG. 3 is a plan view of the semiconductor device A1. FIG. 4 is a fragmentary plan view of the semiconductor device A1. FIG. 5 is a bottom view of the semiconductor device A1. FIG. 6 is a fragmentary bottom view of the semiconductor device A1. FIG. 7 is a side view of the semiconductor device A1. FIG. 8 is a sectional view taken along line VIII-VIII in FIG. 4. FIG. 9 is a sectional view taken along line IX-IX in FIG. 4. FIG. 10 is a fragmentary sectional view schematically showing an example of a bonded structure included in the semiconductor device A1.

The thickness direction z in these figures is defined as the thickness direction of the present disclosure. One side in the thickness direction z is referred to as the z1 side in the z direction, and the opposite side as the z2 side. A direction perpendicular to the thickness direction z is defined as a first direction x. One side in the first direction x is referred to as the x1 side, and the opposite side as the x2 side. The direction perpendicular to the thickness direction z and the first direction x is defined as a second direction y. One side in the second direction y is referred to as the y1 side, and the opposite side as the y2 side.

The semiconductor element 1 is a metal-oxide-semiconductor field-effect transistor (MOSFET), for example. Alternatively, the semiconductor element 1 may be a switching element, such as an insulated gate bipolar transistor (IGBT), or a diode. The following description of the semiconductor device A1 assumes that the semiconductor element 1 is an n-channel, vertical MOSFET. As shown in FIGS. 2, 4, and 8 to 10, the semiconductor element 1 includes a semiconductor layer 10, a first electrode 11, a second electrode 12, and a third electrode 13.

FIG. 10 schematically shows a bonded structure B1 included in the semiconductor device A1. The bonded structure B1 is composed of the semiconductor element 1, the first conductive member 2, the second conductive member 3, the first bonding layer 7, and the second bonding layer 8 that are bonded to one another. For the convenience of description, the first conductive member 2 and the second conductive member 3 are each shown to extend beyond the semiconductor element 1 in a plane that contains the first direction x and the second direction y. In addition, the first bonding layer 7 and the second bonding layer 8 are each shown as a trapezoid that connects the semiconductor element 1 and the first or second conductive member 2 or 3.

The semiconductor layer 10 contains a semiconductor material. Examples of semiconductor materials include silicon (Si), silicon carbide (Sic), and others. In a different embodiment in which the semiconductor element 1 is a lateral switching element, the semiconductor layer 10 may contain gallium nitride (GaN).

As shown in FIG. 10, the first electrode 11 is located on the z1 side in the thickness direction z with respect to the semiconductor layer 10. The first electrode 11 passes the electric current corresponding to the power having been converted by the semiconductor element 1. That is, the first electrode 11 corresponds to the source electrode of the semiconductor element 1.

As shown in FIG. 10, the second electrode 12 is located on the z2 side in the thickness direction z with respect to the semiconductor layer 10. The second electrode 12 passes the electric current corresponding to the power to be converted by the semiconductor element 1. That is, the second electrode 12 corresponds to the drain electrode of the semiconductor element 1.

As shown in FIG. 2, the third electrode 13 is located on the z1 side in the thickness direction z, which is the same as the first electrode 11. The third electrode 13 receives a gate voltage to drive the semiconductor element 1. That is, the third electrode 13 corresponds to the gate electrode of the semiconductor element 1. The third electrode 13 is larger in area than the first electrode 11 as viewed in the thickness direction z.

As shown in FIG. 10, the first electrode 11 includes a first metal layer 111, a second metal layer 112, a first intermediate metal layer 113, and a first barrier metal layer 114. The first metal layer 111 contains a metal having a higher thermal conductivity than solder. Preferably, the first metal layer 111 contains such a metal having a higher thermal conductivity than solder as the main component. The first metal layer 111 contains silver (Ag) or Cu (copper), for example. The following description assumes that the first metal layer 111 contains silver (Ag) as the main component. Specific examples of the first metal layer 111 containing silver (Ag) as the main component include a layer of sintered silver (Ag), a layer of silver (Ag) paste, a layer of silver deposited by sputtering, and a layer of silver (Ag) plating. In the illustrated example, the first metal layer 111 is the surface layer of the first electrode 11.

The second metal layer 112 is interposed between the semiconductor layer 10 and the first metal layer 111. The second metal layer 112 contains aluminum (Al), for example.

The thickness t111 of the first metal layer 111 and the thickness t112 of the second metal layer 112 are not specifically limited. In the present embodiment, the thickness t111 is greater than the thickness t112. In one example, the thickness t111 ranges from 5 μm to 40 μm, and the thickness t112 ranges from 2 μm to 8 μm.

The first intermediate metal layer 113 is interposed between the first metal layer 111 and the second metal layer 112. The first intermediate metal layer 113 contains titanium (Ti) or nickel (Ni), for example. The first intermediate metal layer 113 may have a thickness ranging from 0.1 μm to 0.6 μm, for example. The first intermediate metal layer 113 is provided to prevent damage to the second metal layer 112 or other potential risks, for example, when the first metal layer 111 is formed on the second metal layer 112.

The first barrier metal layer 114 is interposed between the second metal layer 112 and the semiconductor layer 10. The first barrier metal layer 114 contains titanium nitride (TiN), for example. The first barrier metal layer 114 may have a thickness ranging from 0.01 μm to 0.1 μm, for example. The first barrier metal layer 114 is provided to prevent damage to the semiconductor layer 10 or other potential risks, for example, when the second metal layer 112 is formed on the semiconductor layer 10.

The second electrode 12 of the present embodiment includes a fourth metal layer 122 and a second barrier metal layer 124. The fourth metal layer 122 contains aluminum (Al), for example. In the present embodiment, the fourth metal layer 122 is the surface layer of the second electrode 12. The thickness of the fourth metal layer 122 is not specifically limited, and it may be the same as, or different from the thickness t112 of the second metal layer 112.

The second barrier metal layer 124 is interposed between the fourth metal layer 122 and the semiconductor layer 10. The second barrier metal layer 124 contains titanium nitride (TiN), for example. The second barrier metal layer 124 may have a thickness ranging from 0.01 μm to 0.1 μm, for example. The second barrier metal layer 124 is provided to prevent damage to the semiconductor layer 10 or other potential risks, for example, when the fourth metal layer 122 is formed on the semiconductor layer 10.

The first conductive member 2 includes a portion located on the z1 side in the thickness direction z with respect to the semiconductor element 1. The first conductive member 2 contains a conductive material, such as a metal, with copper (Cu) as an example.

As shown in FIGS. 1 to 10, the first conductive member 2 has a first main surface 201 and a second main surface 202. The first main surface 201 is oriented toward the z1 side in the thickness direction z. The second main surface 202 is oriented toward the z2 side in the thickness direction z. The semiconductor element 1 is bonded and electrically connected to the second main surface 202. In the example, the first main surface 201 is covered with the sealing resin 9 as shown in FIGS. 8 and 9.

As shown in FIGS. 1 to 9, the first conductive member 2 includes a first island part 211, a plurality of first terminal parts 212, and a recess 221.

The first island part 211 is bonded and electrically connected to the semiconductor element 1. The first island part 211 includes a portion of the first main surface 201 and a portion of the second main surface 202. The first island part 211 is not limited to a specific shape or size. In the illustrated example, the first island part 211 has such a shape that overlaps with the entire first electrode 11 as viewed in the thickness direction z and that leaves the third electrode 13 exposed.

The plurality of first terminal parts 212 are connected to the end of the first island part 211 on the y2 side in the second direction y. The first terminal parts 212 each extend in the second direction y as viewed in the thickness direction z and are arranged at intervals in the first direction x. The number of the first terminal parts 212 is not specifically limited and may be three as in the illustrated example, or alternatively two, four, or more. Including only one first terminal part 212 is also possible. As shown in FIGS. 1, 2, and 8, each first terminal part 212 includes a portion connected to the first island part 211 and covered with the sealing resin 9, a portion protruding from the sealing resin 9 toward the y2 side in the second direction y, a portion bent toward the z2 side in the thickness direction z, and a portion located on the z2 side in the thickness direction z. The first terminal parts 212 are used as terminals when the semiconductor device A1 is mounted.

The recess 221 is a portion recessed from the first main surface 201 toward the z2 side in the thickness direction z. As viewed in the thickness direction z, the recess 221 overlaps with the first island part 211.

In this example, the first conductive member 2 includes a first substrate 21 and a first plating layer 22 as shown in FIG. 10. The first substrate 21 is the main body of the first conductive member 2 and contains copper (Cu), for example. The first plating layer 22 coats appropriate portions of the first substrate 21 and contains silver (Ag), for example. In this example, the first plating layer 22 coats at least the portions joined by the first bonding layer 7 to the semiconductor element 1.

The first bonding layer 7 bonds and electrically connects the first electrode 11 of the semiconductor element 1 and the second main surface 202 of the first conductive member 2. In this example, the first bonding layer 7 bonds and electrically connects the first metal layer 111 and the first plating layer 22. The first bonding layer 7 is not limited to a specific configuration. In one example, the first bonding layer 7 is made of a conductive bonding material, such as solder or silver (Ag). The thickness t7 of the first bonding layer 7 is not specifically limited either. In the present embodiment, the thickness t7 is smaller than the thickness t111 of the first metal layer 111. In one example, the thickness t7 ranges from 4 μm to 30 μm.

The second conductive member 3 is located on the z2 side in the thickness direction z with respect to the semiconductor element 1. The second conductive member 3 contains a conductive material, such as a metal, with copper (Cu) as an example.

As shown in FIGS. 1 to 10, the second conductive member 3 has a third main surface 301 and a fourth main surface 302. The third main surface 301 is oriented toward the z1 side in the thickness direction z. The fourth main surface 302 is oriented toward the z2 side in the thickness direction z. The semiconductor element 1 is mounted on the third main surface 301. As shown in FIGS. 5 and 6, the fourth main surface 302 is exposed from the sealing resin 9.

As shown in FIGS. 1 to 9, the second conductive member 3 includes a second island part 311, a second terminal part 312, a thin extending part 321, and a through-hole 322.

The second island part 311 is where the semiconductor element 1 is mounted in whole or in part. The second island part 311 includes a portion of the third main surface 301 and a portion of the fourth main surface 302. The second island part 311 is not limited to a specific shape of size. In the illustrated example, the second island part 311 is substantially rectangular as viewed in the thickness direction z.

The second terminal part 312 is connected to the end of the second island part 311 on the y1 side in the second direction y. The second terminal part 312 includes a portion of the third main surface 301 and a portion of the fourth main surface 302. The second terminal part 312 may be used as a terminal when the semiconductor device A1 is mounted.

The thin extending part 321 includes the third main surface 301 but does not include the fourth main surface 302. The thin extending part 321 is thinner in the thickness direction z than the second island part 311 in the thickness direction z. The thin extending part 321 extends from the second island part 311. In the illustrated example, the thin extending part 321 extends from the second island part 311 in the first direction x toward the x1 and x2 sides and also in the second direction y toward the y2 side.

The through-hole 322 passes through the second conductive member 3 in the thickness direction z. In the present embodiment, the through-hole 322 is filled with a portion of the sealing resin 9. When measured perpendicular to the thickness direction z, the through-hole 322 has a larger cross-sectional area at the z2 side in the thickness direction z than that at the z1 side. This helps to prevent detachment of, for example, the second conductive member 3 from the sealing resin 9.

As shown in FIG. 10, in this example, the second conductive member 3 includes a second substrate 31 and a second plating layer 32. The second substrate 31 is the main body of the second conductive member 3 and contains copper (Cu), for example. The second plating layer 32 coats appropriate portions of the second substrate 31 and contains silver (Ag), for example. In this example, the second plating layer 32 coats at least the portions joined by the second bonding layer 8 to the semiconductor element 1.

The second bonding layer 8 bonds and electrically connects the second electrode 12 of the semiconductor element 1 and the third main surface 301 of the second conductive member 3. In this example, the second bonding layer 8 bonds and electrically connects the fourth metal layer 122 and the second plating layer 32. The second bonding layer 8 is not limited to a specific configuration. In one example, the second bonding layer 8 is made of a conductive bonding material, such as solder or silver (Ag). In a different embodiment, the semiconductor element 1 may not have a second electrode 12 on the z2 side in the thickness direction z. Then, the second bonding layer 8 may simply bonds the semiconductor element 1 and the second conductive member 3 without electrical connection.

The third conductive member 4 includes a portion located on the z1 side in the thickness direction z with respect to the semiconductor element 1. The third conductive member 4 contains a conductive material, such as a metal, with copper (Cu) as an example.

As shown in FIGS. 2 to 7, the third conductive member 4 includes a pad part 411 and a third terminal part 412. The pad part 411 is bonded and electrically connected to the third electrode 13 of the semiconductor element 1. The pad part 411 is not limited to a specific shape or size. In the illustrated example, the pad part 411 has such a shape that overlaps with a portion of the third electrode 13 as viewed in the thickness direction z. The pad part 411 is bonded and electrically connected to the third electrode 13 through solder, which is not shown in the figures.

The third terminal part 412 is connected to the end of the pad part 411 on the y2 side in the second direction y. The third terminal part 412 extends in the second direction y as viewed in the thickness direction z. As shown in FIGS. 1, 2 and 7, the third terminal part 412 includes a portion connected to the pad part 411 and covered with the sealing resin 9, a portion protruding from the sealing resin 9 toward the y2 side in the second direction y, a portion bent toward the z2 side in the thickness direction z, and a portion located on the z2 side in the thickness direction z. As viewed in the first direction x, the third terminal part 412 has such a shape and size that roughly overlap with the first terminal part 212. The third terminal part 412 is used as a terminal when the semiconductor device A1 is mounted.

The sealing resin 9 covers the semiconductor element 1 and a portion of each of the first conductive member 2, the second conductive member 3, and the third conductive member 4. The sealing resin 9 is electrically insulating. Examples of the sealing resin 9 includes black epoxy resin containing filler. The sealing resin 9 is not limited to a specific shape. As shown in FIGS. 1 to 9, the sealing resin 9 of the present embodiment includes a first resin surface 91, a second resin surface 92, a third resin surface 93, a fourth resin surface 94, a fifth resin n surface 95, and a sixth resin surface 96.

The first resin surface 91 is oriented toward the z1 side in the thickness direction z. The second resin surface 92 is oriented toward the z2 side in the thickness direction z. The fourth main surface 302 of the second conductive member 3 is exposed at the second resin surface 92. In the illustrated example, the first resin surface 91 and the second resin surface 92 are each flat, but other surface geometries, such as curved or bent, are also possible. In the illustrated example, the second resin surface 92 and the fourth main surface 302 are flush with each other.

The third resin surface 93 is oriented toward the x1 side in the first direction x. The fourth resin surface 94 is oriented toward the x2 side in the first direction x. In the illustrated example, the third resin surface 93 and the fourth resin surface 94 are each lightly bent, but other surface geometries, such as curved or flat, are also possible.

The fifth resin surface 95 is oriented toward the y1 side in the second direction y. The sixth resin surface 96 is oriented toward the y2 side in the second direction y. In the illustrated example, the fifth resin surface 95 and the sixth resin surface 96 are slightly bent, but other surface geometries, such as curved or flat, are also possible. In the present embodiment, the first terminal parts 212 and the third terminal part 412 protrude from the sixth resin surface 96.

The following describes of the operation of the semiconductor device A1.

According to the present embodiment as shown in FIG. 10, the first electrode 11 includes the first metal layer 111. The first metal layer 111 contains a metal having a higher conductivity than solder. Thus, when the thermal semiconductor layer 10 of the semiconductor element 1 repeatedly generates heat during operation of the semiconductor device A1, the heat is rapidly conducted from the semiconductor layer 10 to the first metal layer 111, increasing the heat flux released from the semiconductor layer 10. This prevents an excessive transient temperature rise in the semiconductor layer 10, allowing the semiconductor element 1 to operate more appropriately. In particular, when the semiconductor element 1 is a vertical switching element, the semiconductor layer 10 generates significant heat at the portion on the z1 side in the thickness direction z during the operation of the semiconductor device A1. Given this pattern of heat generation, providing the first metal layer 111 is an effective measure to reduce the temperature rise caused by the heat.

The first metal layer 111 containing silver (Ag) helps to increase the heat flux released from the semiconductor layer 10. Here, using silver (Ag) as the main component of the first metal layer 111 is preferable for increasing the heat flux. In addition, using sintered silver (Ag) is suitable for forming the first metal layer 111 having a desired shape and thickness.

The thickness t111 of the first metal layer 111 is greater than the thickness t112 of the second metal layer 112. This ensures more rapid transfer from of heat the semiconductor layer 10 to the first metal layer 111 through the second metal layer 112. Also, the thickness t7 of the first bonding layer 7 is smaller than the thickness t111 of the first metal layer 111. This ensures efficient transfer of heat from the first metal layer 111 to the first conductive member 2, thus improving the heat dissipation from the semiconductor layer 10.

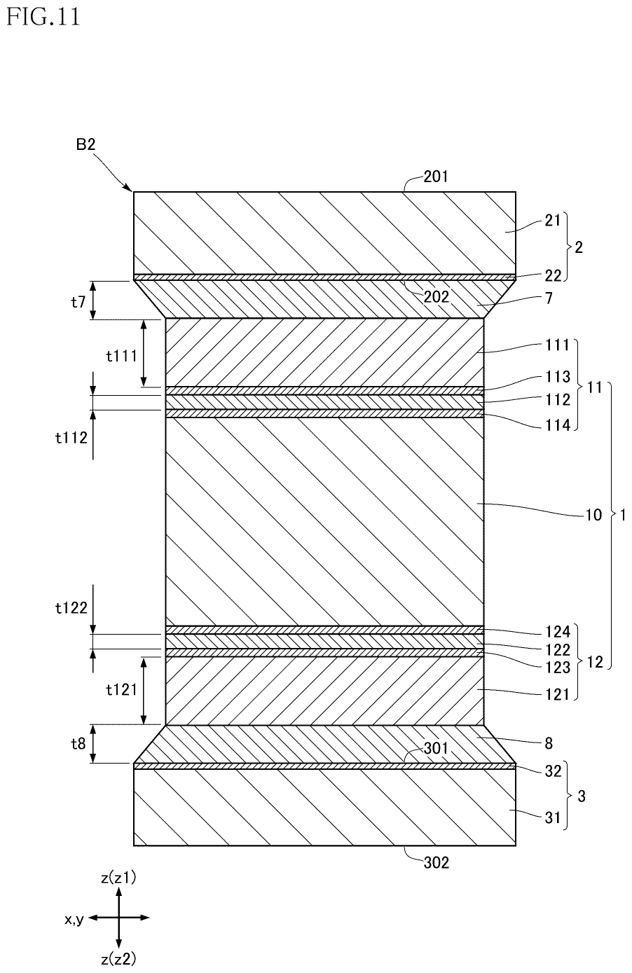

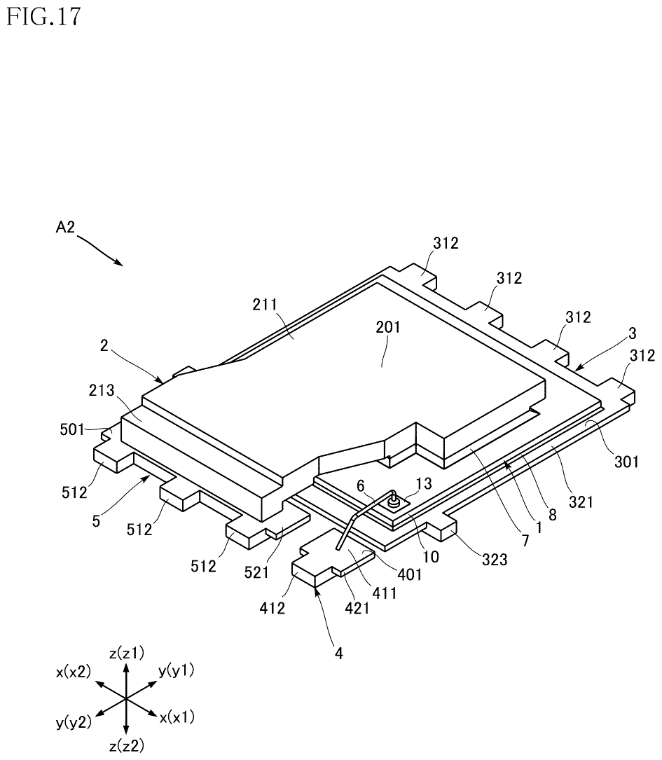

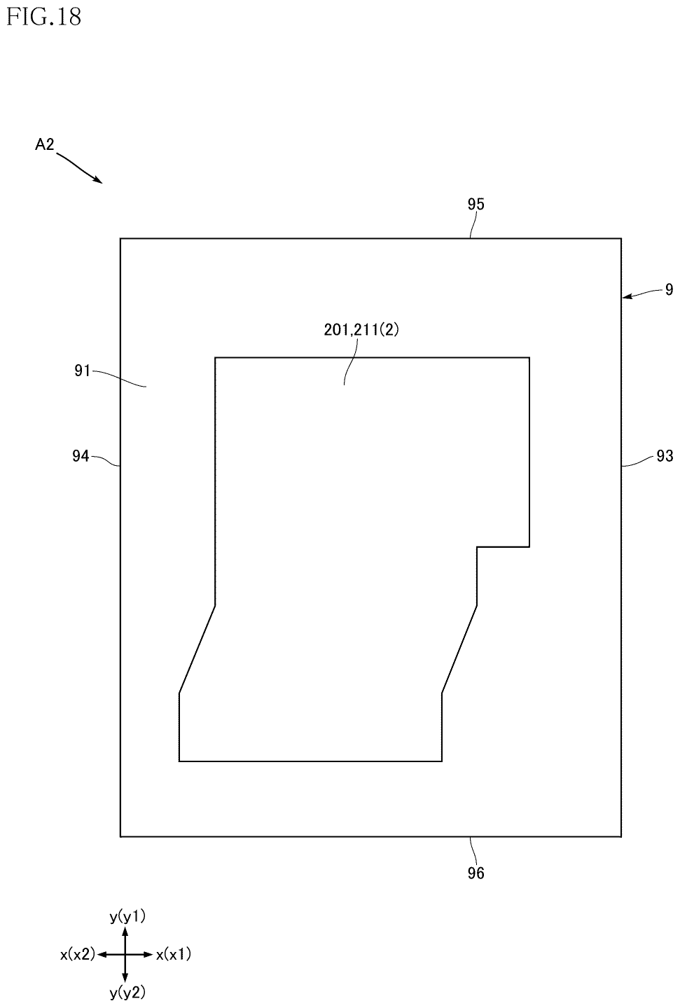

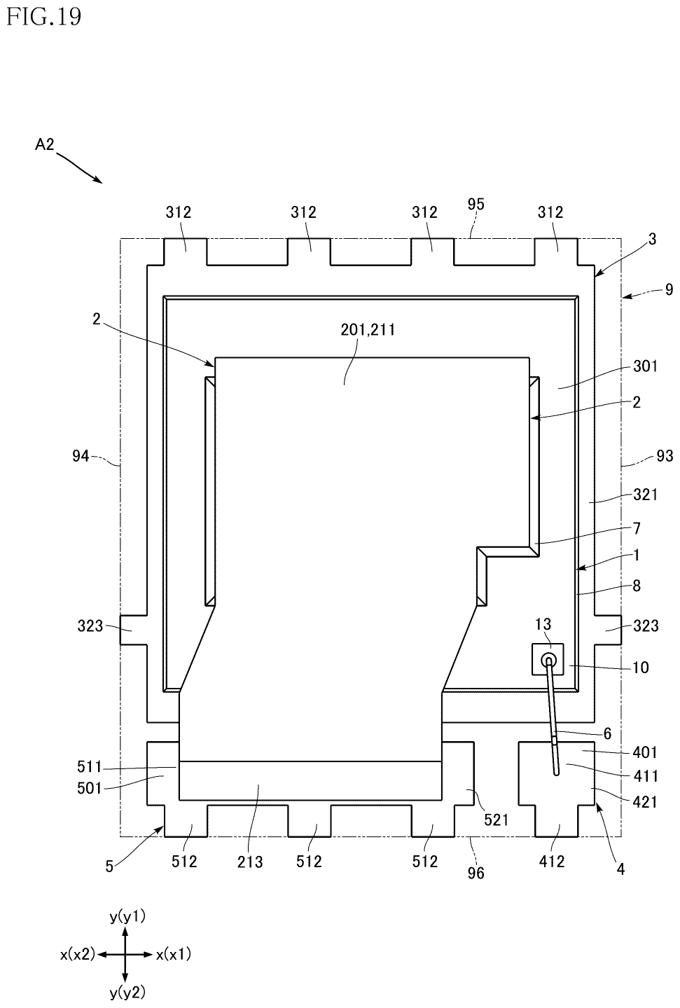

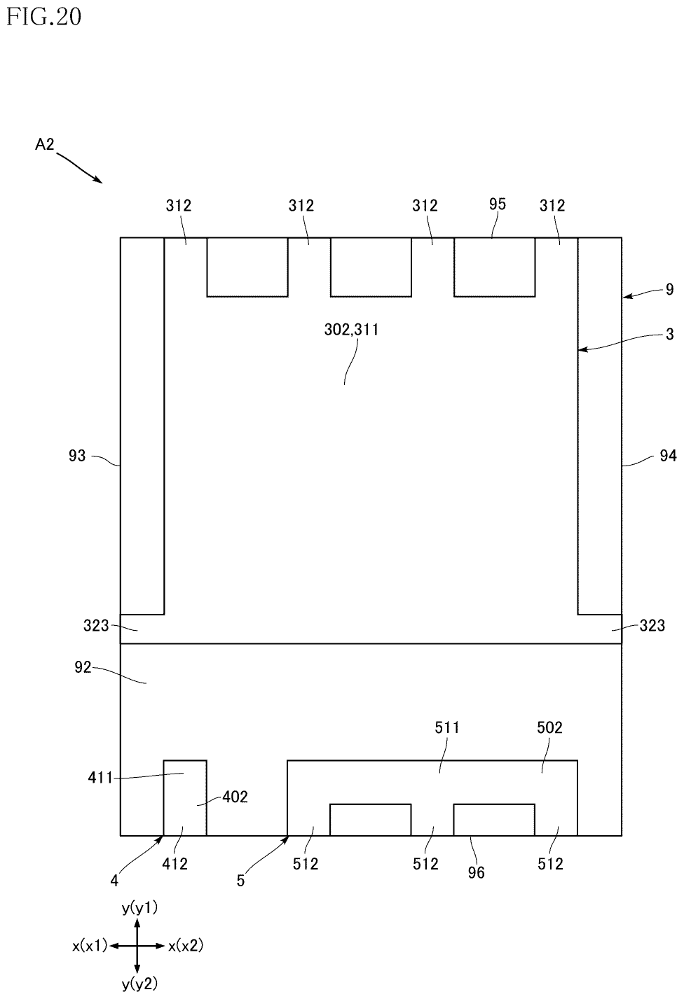

FIGS. 11 to 25 show variations and other embodiments of the present disclosure. In these figures, elements that are identical or similar to those of the above-described embodiment are indicated by the same reference numerals. In addition, configurations of elements and components in each embodiment and variation may be combined in any manner, provided that no technical inconsistencies arise.

FIGS. 11 to 14 schematically show other examples of the bonded structure included in the semiconductor device A1. The bonded structure B1 described above and the bonded structures B2 to B5 described below are applicable as appropriate to the semiconductor device A1 and also to a variety of semiconductor devices, including those described below.

The bonded structure B2 shown in FIG. 11 differs from the bonded structure B1, mainly in the configuration of the second electrode 12. The second electrode 12 of this example includes a third metal layer 121, a fourth metal layer 122, a second intermediate metal layer 123, and a second barrier metal layer 124. The third metal layer 121 contains a metal having a higher thermal conductivity than solder. Preferably, the third metal layer 121 contains such a metal having a higher thermal conductivity as the main component. The third metal layer 121 contains silver (Ag) or Cu (copper), for example. The following description assumes that the third metal layer 121 contains silver (Ag) as the main component. Specific examples of the third metal layer 121 with silver (Ag) as the main component include a layer of sintered silver (Ag), a layer of silver (Ag) paste, a layer of silver deposited by sputtering, and a layer of silver (Ag) plating. In the illustrated example, the third metal layer 121 is the surface layer of the second electrode 12.

The fourth metal layer 122 is interposed between the semiconductor layer 10 and the third metal layer 121. The fourth metal layer 122 contains aluminum (Al), for example.

The thickness t121 of the third metal layer 121 and the thickness t122 of the fourth metal layer 122 are not specifically limited. In the present embodiment, the thickness t121 is greater than the thickness t122. In one example, the thickness t121 ranges from 5 μm to 10 μm, and the thickness t122 ranges from 2 μm to 8 μm.

The second intermediate metal layer 123 is interposed between the third metal layer 121 and the fourth metal layer 122. The second intermediate metal layer 123 may contain titanium (Ti), nickel (Ni), or other suitable metals. The second intermediate metal layer 123 may have a thickness ranging from 0.1 μm to 0.6 μm, for example. The second intermediate metal layer 123 is provided to prevent damage to the fourth metal layer 122 or other potential risks, for example, when the third metal layer 121 is formed on the fourth metal layer 122.

The second barrier metal layer 124 is interposed between the fourth metal layer 122 and the semiconductor layer 10. The second barrier metal layer 124 contains titanium nitride (TiN), for example. The second barrier metal layer 124 may have a thickness ranging from 0.01 μm to 0.1 μm, for example. The second barrier metal layer 124 is provided to prevent damage to the semiconductor layer 10 or other potential risks, for example, when the fourth metal layer 122 is formed on the semiconductor layer 10.

The second bonding layer 8 is similar in configuration to the second bonding layer 8 of the bonded structure B1 described above. The thickness t8 of the second bonding layer 8 is not specifically limited. In the present embodiment, the thickness t8 is smaller than the thickness t121 of the third metal layer 121. In one example, the thickness t8 ranges from 5 μm to 30 μm.

The configuration of this example increases the heat flux released from the semiconductor element 1, allowing the semiconductor element 1 to operate more appropriately. In this example, the second electrode 12 includes the third metal layer 121. The third metal layer 121 contains a metal having a higher thermal conductivity than solder. Thus, when the semiconductor layer 10 of the semiconductor element 1 repeatedly generates heat during operation of the semiconductor device A1, the heat is rapidly conducted from the semiconductor layer 10 to the third metal layer 121, increasing the heat flux released from the semiconductor layer 10. This further helps to prevent an excessive transient temperature rise of the semiconductor layer 10.

The third metal layer 121 containing silver (Ag) serves to further increase the heat flux released from the semiconductor layer 10. Here, using silver (Ag) as the main component of the third metal layer 121 is preferable for increasing the heat flux. In addition, using sintered silver (Ag) for the third metal layer 121 is suitable for forming the third metal layer 121 having a desired shape and thickness.

The thickness t121 of the third metal layer 121 is greater than the thickness t122 of the fourth metal layer 122. This ensures more rapid transfer of heat from the semiconductor layer 10 to the third metal layer 121 through the fourth metal layer 122. Also, the thickness t8 of the second bonding layer 8 is smaller than the thickness t121 of the third metal layer 121. This ensures efficient transfer of heat from the third metal layer 121 to the second conductive member 3, thus improving the heat dissipation from the semiconductor layer 10.

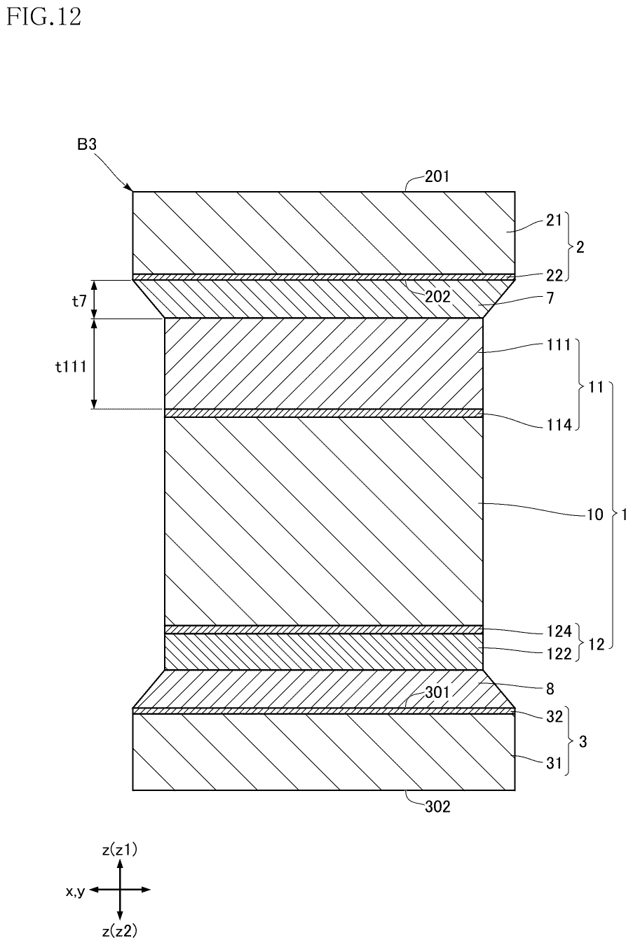

The bonded structure B3 shown in FIG. 12 differs from the bonded structure B2 described above, mainly in the configuration of the first electrode 11. The first electrode 11 of this example includes a first metal layer 111 and a first barrier metal layer 114, with the first metal layer 111 formed on the first barrier metal layer 114. Also in this example, the thickness t111 is greater than the thickness t7. In this example, the thickness t111 may range from 5 μm to 40 μm, for example.

The configuration of this example increases the heat flux released from the semiconductor element 1, allowing the semiconductor element 1 to operate more appropriately. In this example, in addition, heat of the semiconductor layer 10 is transferred more directly to the first metal layer 111. This is expected to further increase the heat flux released. In addition, the first metal layer 111 with an increased thickness t111 has a higher heat capacity and thus more reliably prevents an excessive transient temperature rise of the semiconductor layer 10.

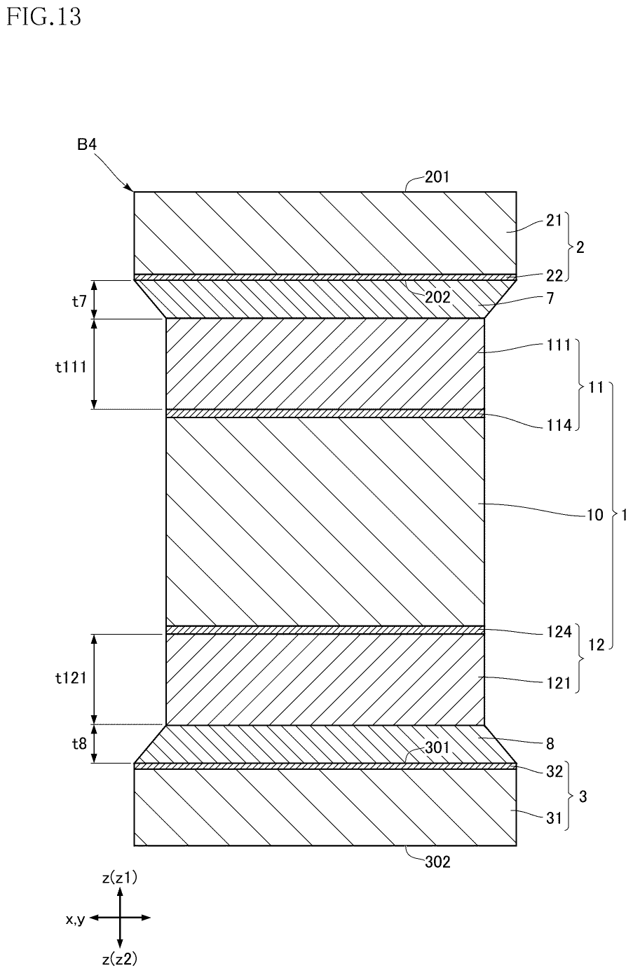

The bonded structure B4 shown in FIG. 13 differs from the bonded structure B3 described above, mainly in the configuration of the second electrode 12. The second electrode 12 of this example includes a third metal layer 121 and a second barrier metal layer 124, with the third metal layer 121 formed on the second barrier metal layer 124. In this example, the thickness t121 is greater than the thickness t8. In this example, the thickness t121 may range from 5 μm to 40 μm, for example.

The configuration of this example increases the heat flux released from the semiconductor element 1, allowing the semiconductor element 1 to operate more appropriately. In this example, in addition, heat of the semiconductor layer 10 is transferred more directly to the third metal layer 121. This is expected to further increase the heat flux released. In addition, the third metal layer 121 with an increased thickness t121 has a higher heat capacity and thus more reliably prevents an excessive transient temperature rise of the semiconductor layer 10.

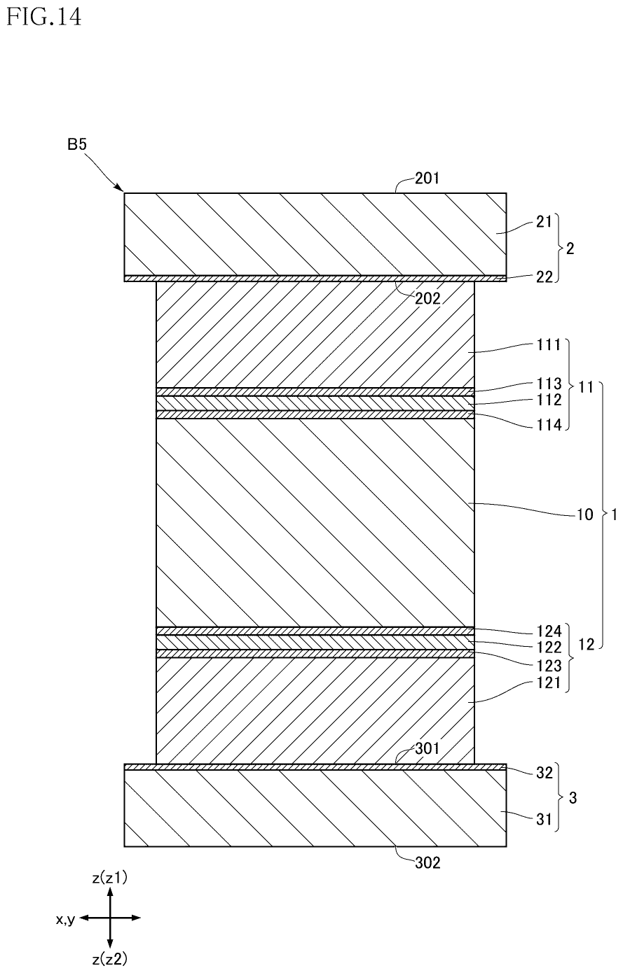

The bonded structure B5 shown in the FIG. 14 differs from the bonded structures B1 to B4 mainly in the absence of the first bonding layer 7 and the second bonding layer 8. In this example, the first metal layer 111 of the first electrode 11 is bonded directly to the first plating layer 22 of the first conductive member 2. This configuration is achieved, for example, by solid-state diffusion bonding of the first metal layer 111 and the first plating layer 22 both containing the same metal, such as silver (Ag), as the main component. Alternatively, the first metal layer 111 may be composed of sintered silver (Ag). In this case, a paste for forming the first metal layer 111 by sintering is applied to the first intermediate metal layer 113, and a first conductive member 2 is placed over the applied paste, followed by sintering of the paste. As a result, the first metal layer 111 is formed, and the first electrode 11 and the first conductive member 2 are joined together.

In this example, the third metal layer 121 of the second electrode 12 is bonded directly to the second plating layer 32 of the second conductive member 3. This configuration is achieved, for example, by solid-state diffusion bonding of the third metal layer 121 and the second plating layer 32 both containing the same metal, such as silver (Ag), as the main component. Alternatively, the third metal layer 121 may be composed of sintered silver (Ag). In this case, a paste for forming the third metal layer 121 by sintering is applied to the second conductive member 3, and a second intermediate metal layer 123 is placed over the applied paste, followed by sintering of the paste. As a result, the third metal layer 121 is formed, and the second electrode 12 and the second conductive member 3 are joined together.

The configuration of this example increases the heat flux released from the semiconductor element 1, allowing the semiconductor element 1 to operate more appropriately. In addition, this example allows the direct heat transfer from the first metal layer 111 to the first conductive member 2 without passing through the first bonding layer 7. This configuration further helps to prevent an excessive transient temperature rise of the semiconductor layer 10 and to promote steady heat dissipation over a longer period of time. In addition, heat is transferred from the third metal layer 121 directly to the second conductive member 3 without passing through the second bonding layer 8. This further helps to prevent an excessive transient temperature rise of the semiconductor layer 10 and also to promote steady heat dissipation over a longer period of time.

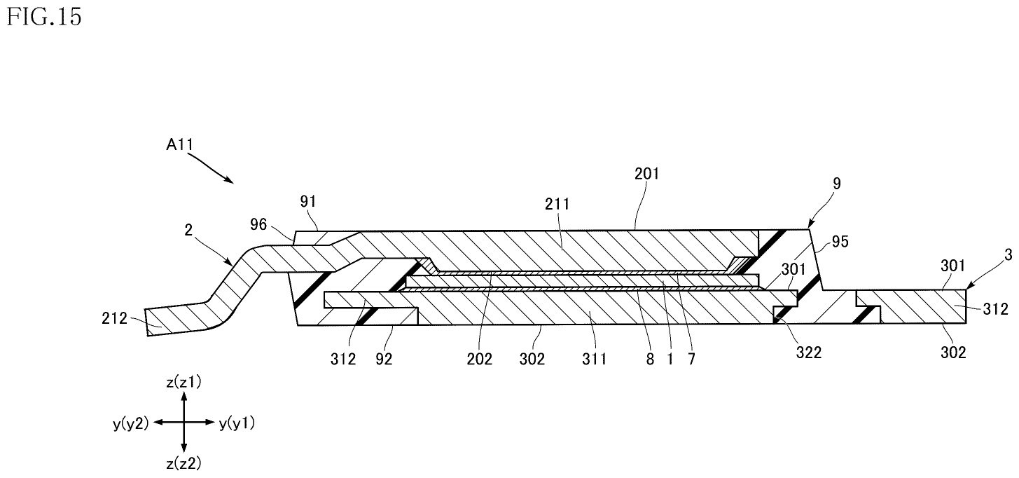

FIG. 15 shows a first variation of the semiconductor device A1. A semiconductor device A11 of this variation differs from the semiconductor device A1 mainly in the configurations of the first conductive member 2 and the sealing resin 9.

In this variation, the first conductive member 2 has a first main surface 201 that is exposed at the first resin surface 91 of the sealing resin 9. The first conductive member 2 is not formed with the recess 221 described above. The first main surface 201 and the first resin surface 91 are flush with each other.

The configuration of this variation increases the heat flux released from the semiconductor element 1, allowing the semiconductor element 1 to operate more appropriately. In addition, the first main surface 201 of the first conductive member 2 serves to efficiently dissipate heat from the semiconductor device A11 to the outside.

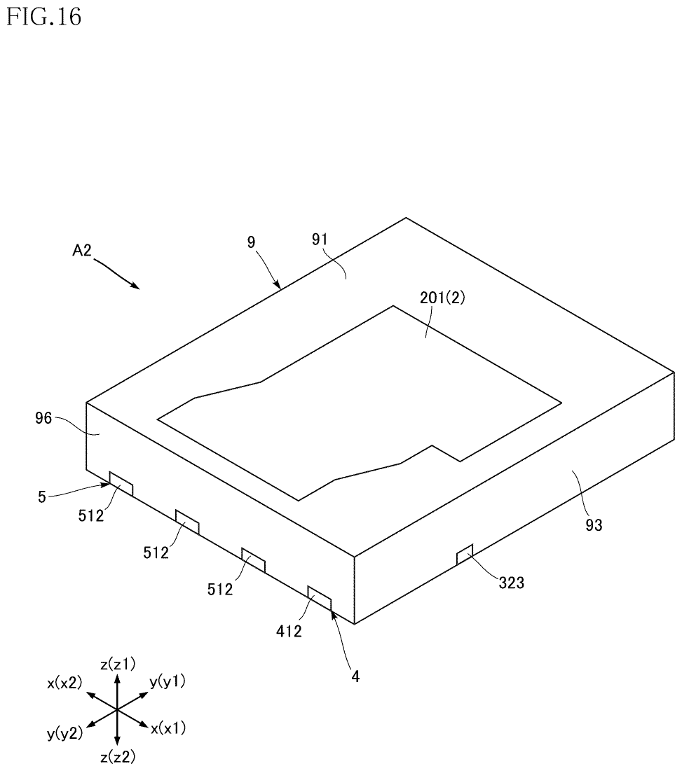

FIGS. 16 to 23 show a semiconductor device according to a second embodiment of the present disclosure. The semiconductor device A2 of this embodiment includes a semiconductor element 1, a first conductive member 2, a second conductive member 3, a third conductive member 4, a fourth conductive member 5, a fifth conductive member 6, and a sealing resin 9.

The first conductive member 2 includes a first island part 211 and a connecting part 213. The first island part 211 includes a portion of each of the first main surface 201 and the second main surface 202. The first island part 211 is bonded and electrically connected to the first electrode 11 of the semiconductor element 1. The connecting part 213 is a portion of the first island part 211 on the y2 side in the second direction y. The connecting part 213 extends from the first island part 211 toward the y2 side in the second direction y and then toward the z2 side in the thickness direction z.

The first main surface 201 of the first conductive member 2 is exposed at the first resin surface 91 of the sealing resin 9. In illustrated example, the first main surface 201 and the first resin surface 91 are flush with each other.

The fourth conductive member 5 is located on the z2 side in the thickness direction z with respect to the first conductive member 2. The fourth conductive member 5 contains a conductive material, such as a metal, with copper (Cu) as an example. In addition, a plating layer (not shown) may be provided to coat appropriate portions of the fourth conductive member 5. The fourth conductive member 5 is bonded and electrically connected to the connecting part 213 of the first conductive member 2 through a conductive bonding material 59, such as solder.

As shown in FIGS. 16, 17, and 19 to 22, the fourth conductive member 5 has a seventh main surface 501 and an eighth main surface 502. The seventh main surface 501 is oriented toward the z1 side in the thickness direction z. The eighth main surface 502 is oriented toward the z2 side in the thickness direction z. The connecting part 213 of the first conductive member 2 is bonded and electrically connected to the seventh main surface 501 through the conductive bonding material 59. The seventh main surface 501 is covered with the sealing resin 9. The eighth main surface 502 is exposed at the second resin surface 92 of the sealing resin 9. In this example, the eighth main surface 502 and the second resin surface 92 are flush with each other.

The fourth conductive member 5 includes a pad part 511, a plurality of fourth terminal parts 512, and a thin extending part 521.

The pad part 511 is bonded to and electrically connected to the first conductive member 2. The pad part 511 includes a portion of the seventh main surface 501 and a portion of the eighth main surface 502. The pad part 511 is not limited to a specific shape or size. In the illustrated example, the pad part 511 as viewed in the thickness direction z has a rectangular shape that is longer in the first direction x.

The plurality of fourth terminal parts 512 are connected to the end of the pad part 511 on the y2 side in the second direction y. The fourth terminal parts 512 each extend in the second direction y as viewed in the thickness direction z and are arranged at intervals in the first direction x. The number of the fourth terminal parts 512 is not specifically limited, and may be three as in the illustrated example or alternatively two, four, or more. Including only one fourth terminal part 512 is also possible. As shown in FIG. 22, each fourth terminal part 512 is exposed at both the second resin surface 92 and the sixth resin surface 96 of the sealing resin 9. The end surface of each fourth terminal part 512 is flush with the sixth resin surface 96. The fourth terminal parts 512 are used as terminals when the semiconductor device A2 is mounted.

The thin extending part 521 includes the seventh main surface 501 but does not include the eighth main surface 502. The thin extending part 521 is thinner in the thickness direction z than the pad part 511 in the thickness direction z. The thin extending part 521 extends from the pad part 511. In the illustrated example, the thin extending part 521 extends from the pad part 511 toward both the x1 and x2 sides in the first direction x and also toward the y1 side in the second direction y.

As shown in FIGS. 16, 17, and 19 to 23, the second conductive member 3 of the present embodiment includes a second island part 311, a plurality of second terminal parts 312, a thin extending part 321, and a thick extending part 323.

The second island part 311 is where the semiconductor element 1 is mounted in whole or in part. The second island part 311 is similar in configuration to that of the semiconductor device A1.

The second terminal parts 312 are all connected to the end of the second island part 311 on the y1 side in the second direction y. Each second terminal part 312 includes a portion of the third main surface 301 and a portion of the fourth main surface 302. The second terminal parts 312 may be used as terminals when the semiconductor device A2 is mounted.

The plurality of second terminal parts 312 are all connected to the end of the second island part 311 on the y1 side in the second direction y. The second terminal parts 312 each extend in the second direction y as viewed in the thickness direction z and are arranged at intervals in the first direction x. The number of the second terminal parts 312 is not specifically limited, and may be four as in the illustrated example or alternatively two, three, five, or more. Including only one second terminal part 312 is also possible. As shown in FIG. 22, each second terminal part 312 is exposed at the second resin surface 92 and the fifth resin surface 95 of the sealing resin 9. The end surface of each second terminal part 312 is flush with the fifth resin surface 95. The second terminal parts 312 are used as terminals when the semiconductor device A2 is mounted.

The thick extending part 323 extends in the first direction x from the second island part 311. The thick extending part 323 includes a portion of the third main surface 301 and a portion of the fourth main surface 302. In the illustrated example, the second conductive member 3 includes two thick extending parts 323. The thick extending parts 323 extend oppositely from the second island part 311 in the first direction x. The two thick extending parts 323 are each exposed at the second resin surface 92 and one of the third resin surface 93 or the fourth resin surface 94 of the sealing resin 9. The end surface of each thick extending part 323 is flush with a corresponding one of the third resin surface 93 and the fourth resin surface 94.

The third conductive member 4 is located on the y2 side in the second direction y with respect to the second conductive member 3, and on the x1 side in the first direction x with respect to the fourth conductive member 5. The third conductive member 4 contains a conductive material, such as a metal, with copper (Cu) as an example. In addition, a plating layer (not shown) may be provided to coat appropriate portions of the third conductive member 4. The fifth conductive member 6 is connected to the third conductive member 4.

As shown in FIGS. 16, 17, and 19 to 21, the third conductive member 4 has a fifth main surface 401 and a sixth main surface 402. The fifth main surface 401 is oriented toward the z1 side in the thickness direction z. The sixth main surface 402 is oriented toward the z2 side in the thickness direction z. The fifth conductive member 6 is connected to the fifth main surface 401. The fifth main surface 401 is covered with the sealing resin 9. The sixth main surface 402 is exposed at the second resin surface 92 of the sealing resin 9. In this example, the sixth main surface 402 and the second resin surface 92 are flush with each other.

The third conductive member 4 includes a pad part 411, a third terminal part 412, and an thin extending part 421.

The pad part 411 is where the fifth conductive member 6 is connected. The pad part 411 includes a portion of the fifth main surface 401 and a portion of the sixth main surface 402. The pad part 411 is not limited to a specific shape or size. In the illustrated example, the pad part 411 has a rectangular shape as viewed in the thickness direction z. The pad part 411 measured in the first direction x is smaller than the pad part 511 measured in the first direction x.

The third terminal part 412 is connected to the end of the pad part 411 on the y2 side in the second direction y.

The third terminal part 412 extends in the second direction y as viewed in the thickness direction z. The number of the third terminal parts 412 is not specifically limited, and may be one as in the illustrated example or alternatively two or more. The third terminal part 412 is exposed at both the second resin surface 92 and the sixth resin surface 96 of the sealing resin 9. The end surface of the third terminal part 412 is flush with the sixth resin surface 96. The third terminal part 412 is used as a terminal when the semiconductor device A2 is mounted.

The thin extending part 421 includes the fifth main surface 401 but does not include the sixth main surface 402. The thin extending part 421 is thinner in the thickness direction z than the pad part 411 in the thickness direction z. The thin extending part 421 extends from the pad part 411. In the illustrated example, the thin extending part 421 extends from the pad part 411 toward both the x1 and x2 sides in the first direction x and also toward the y1 side in the second direction y.

The fifth conductive member 6 is connected to the third electrode 13 of the semiconductor element 1 and the pad part 411 of the third conductive member 4. The fifth conductive member 6 is composed of a wire that contains gold (Au), a copper (Cu), or aluminum (Al), for example, as the main component. Alternatively, the fifth conductive member 6 may be composed of a flat metal ribbon or a lead, instead of a wire.

The configuration of the present embodiment increases the heat flux released from the semiconductor element 1, allowing the semiconductor element 1 to operate more appropriately. In addition, with the first conductive member 2 and the fourth conductive member 5 provided as separate bodies, it is easier to manufacture the first conductive member 2 with a greater thickness in the thickness direction z than the fourth conductive member 5. The first conductive member 2 having a greater thickness further increases the heat dissipation from the semiconductor element 1 (the semiconductor layer 10).

FIG. 24 shows a first variation of the semiconductor device A2. A semiconductor device A21 of this variation differs from the semiconductor device A2 mainly in the configuration of the first conductive member 2.

In this variation, the first conductive member 2 has a first island part 211 that protrudes from the first resin surface 91 of the sealing resin 9 toward the z1 side in the thickness direction z. The first main surface 201 is located farther on the z1 side in the thickness direction z than the first resin surface 91.

The configuration of this variation increases the heat flux released from the semiconductor element 1, allowing the semiconductor element 1 to operate more appropriately. In addition, when the semiconductor device A21 is mounted onto a heatsink (not shown), the first main surface 201 can be easily pressed against the heatsink as the first main surface 201 is located farther on the z1 side in the thickness direction z than the first resin surface 91. This helps to increase the heat dissipation from the semiconductor device A21.

FIG. 25 shows a second variation of the semiconductor device A2. A semiconductor device A22 of this variation differs from the above-described semiconductor devices mainly in the configuration of the first conductive member 2.

In this variation, the first conductive member 2 includes a plurality of protrusions 223. The protrusions 223 protrude from the first main surface 201 toward the z1 side in the thickness direction z. The protrusions 223 are not specifically limited in shape and arrangement as viewed in the thickness direction z. For example, the protrusions 223 may be arranged in a matrix as viewed in the thickness direction z. Also, the protrusions 223 may each have a fin-like shape extending in the first direction x or the second direction y. The relative positions of the first main surface 201 and the first resin surface 91 are not specifically limited. For example, the first main surface 201 may be located farther on the z1 side in the thickness direction z than the first resin surface 91.

The configuration of this variation increases the heat flux released from the semiconductor element 1, allowing the semiconductor element 1 to operate more appropriately. In addition, the first conductive member 2 with the plurality of protrusions 223 has a larger surface area contributing to heat dissipation. This helps to increase the heat dissipation from the semiconductor device A22.

The semiconductor device according to the present disclosure is not limited to the embodiments described above. Various modifications in design may be made freely in the specific structure of each part of the semiconductor device according to the present disclosure.

The present disclosure includes the embodiments described in the following clauses.

### Clause 1.

A semiconductor device comprising:
a semiconductor element including a semiconductor layer and a first electrode disposed on a first side in a thickness direction with respect to the semiconductor layer;
a first conductive member bonded to the first electrode;
a second conductive member bonded to the semiconductor element on a second side in the thickness direction; and
a sealing resin including a first resin surface and a second resin surface respectively oriented toward the first side and the second side in the thickness direction, the sealing resin covering the semiconductor element and at least a portion of each of the first conductive member and the second conductive member,
wherein the first electrode includes a first metal layer that contains a metal having a higher thermal conductivity than solder.

### Clause 2.

The semiconductor device according to Clause 1, wherein the first metal layer contains Ag or Cu.

### Clause 3.

The semiconductor device according to Clause 1 or 2, wherein the second conductive member is exposed at the second resin surface.

### Clause 4.

The semiconductor device according to any one of Clauses 1 to 3, wherein the first conductive member is exposed at the first resin surface.

### Clause 5.

The semiconductor device according to Clause 4, wherein the first conductive member includes a protrusion protruding toward the first side in the thickness direction.

### Clause 6.

The semiconductor device according to any one of Clauses 1 to 5, wherein the first electrode includes a second metal layer disposed between the semiconductor layer and the first metal layer.

### Clause 7.

The semiconductor device according to Clause 6, wherein the second metal layer contains Al.

### Clause 8.

The semiconductor device according to Clause 6 or 7, wherein the first metal layer is thicker than the second metal layer.

### Clause 9.

The semiconductor device according to any one of Clauses 1 to 8, further comprising a first bonding layer that bonds the first electrode and the first conductive member.

### Clause 10.

The semiconductor device according to Clause 9, wherein the first metal layer is thicker than the first bonding layer.

### Clause 11.

The semiconductor device according to any one of Clauses 1 to 8, wherein the first metal layer is in direct contact with the first conductive member.

### Clause 12.

The semiconductor device according to any one of Clauses 1 to 11, wherein the semiconductor element includes a second electrode disposed on the second side in the thickness direction with respect to the semiconductor layer, and the second electrode includes a third metal layer that contains a metal having a higher thermal conductivity than solder.

### Clause 13.

The semiconductor device according to Clause 12, wherein the third metal layer contains Ag or Cu.

### Clause 14.

The semiconductor device according to Clause 12 or 13, further comprising a second bonding layer that bonds the second electrode and the second conductive member, wherein the third metal layer is thicker than the second bonding layer.

### Clause 15.

The semiconductor device according to any one of Clauses 1 to 14, further comprising a third conductive member that is electrically connected to a third electrode,
wherein the semiconductor element includes the third electrode disposed on the first side in the thickness direction with respect to the semiconductor layer.

### Clause 16.

The semiconductor device according to any one of Clauses 1 to 15, wherein the first conductive member includes a first terminal part that includes a portion located on the second side in the thickness direction with respect to the semiconductor element.

### Clause 17.

The semiconductor device according to Clause 15, further comprising a fourth conductive member electrically connected to the first conductive member,
wherein the fourth conductive member includes a portion located on the second side in the thickness direction with respect to the semiconductor element.

### REFERENCE NUMERALS

A1, A11, A2, A21, A22: semiconductor device
B1, B2, B3, B4, B5: bonded structure
1: semiconductor element 2: first conductive member
3: second conductive member 4: third conductive member
5: fourth conductive member 6: fifth conductive member
7: first bonding layer 8: second bonding layer
9: sealing resin 10: semiconductor layer
11: first electrode 12: second electrode
13: third electrode 21: first substrate
31: second substrate 22: first plating layer
59: conductive bonding material 32: second plating layer
92: second resin surface 91: first resin surface
93: third resin surface
95: fifth resin surface
111: first metal layer
94: fourth resin surface
96: sixth resin surface
112: second metal layer
113: first intermediate metal layer
114: first barrier metal layer
121: third metal layer 122: fourth metal layer
123: second intermediate metal layer
124: second barrier metal layer
201: first main surface 202: second main surface
211: first island part 212: first terminal part
213: connecting part 221: recess
223: protrusion 301: third main surface
302: fourth main surface 311: second island part
312: second terminal part 321: thin extending part
322: through-hole 323: thick extending part
401: fifth main surface 402: sixth main surface
411: pad part 412: third terminal part
421: thin extending part 501: seventh main surface
502: eighth main surface 511: pad part
512: fourth terminal part 521: thin extending part
t111, t112, t121, t122, t7, t8: thickness
x: first direction y: second direction
z: thickness direction

1. A semiconductor device comprising:
a semiconductor element including a semiconductor layer and a first electrode disposed on a first side in a thickness direction with respect to the semiconductor layer;
a first conductive member bonded to the first electrode;
a second conductive member bonded to the semiconductor element on a second side in the thickness direction; and
a sealing resin including a first resin surface and a second resin surface respectively oriented toward the first side and the second side in the thickness direction, the sealing resin covering the semiconductor element and at least a portion of each of the first conductive member and the second conductive member,
wherein the first electrode includes a first metal layer that contains a metal having a higher thermal conductivity than solder.

2. The semiconductor device according to claim 1, wherein the first metal layer contains Ag or Cu.

3. The semiconductor device according to claim 1, wherein the second conductive member is exposed at the second resin surface.

4. The semiconductor device according to claim 1, wherein the first conductive member is exposed at the first resin surface.

5. The semiconductor device according to claim 4, wherein the first conductive member includes a protrusion protruding toward the first side in the thickness direction.

6. The semiconductor device according to claim 1, wherein the first electrode includes a second metal layer disposed between the semiconductor layer and the first metal layer.

7. The semiconductor device according to claim 6, wherein the second metal layer contains Al.

8. The semiconductor device according to claim 6, wherein the first metal layer is thicker than the second metal layer.

9. The semiconductor device according to claim 1, further comprising a first bonding layer that bonds the first electrode and the first conductive member.

10. The semiconductor device according to claim 9, wherein the first metal layer is thicker than the first bonding layer.

11. The semiconductor device according to claim 1, wherein the first metal layer is in direct contact with the first conductive member.

12. The semiconductor device according to claim 1, wherein the semiconductor element includes a second electrode disposed on the second side in the thickness direction with respect to the semiconductor layer, and
the second electrode includes a third metal layer that contains a metal having a higher thermal conductivity than solder.

13. The semiconductor device according to claim 12, wherein the third metal layer contains Ag or Cu.

14. The semiconductor device according to claim 12, further comprising a second bonding layer that bonds the second electrode and the second conductive member,
wherein the third metal layer is thicker than the second bonding layer.

15. The semiconductor device according to claim 1, further comprising a third conductive member that is electrically connected to a third electrode,
wherein the semiconductor element includes the third electrode disposed on the first side in the thickness direction with respect to the semiconductor layer.

16. The semiconductor device according to claim 1, wherein the first conductive member includes a first terminal part that includes a portion located on the second side in the thickness direction with respect to the semiconductor element.

17. The semiconductor device according to claim 15, further comprising a fourth conductive member electrically connected to the first conductive member,
wherein the fourth conductive member includes a portion located on the second side in the thickness direction with respect to the semiconductor element.
